(19) United States
(12) Patent Application Publication
(10) Pub. No.: US 2010/0319612 A1
(43) Pub. Date: Dec. 23, 2010

(54) METHOD OF PRODUCING SILICON SINGLE CRYSTAL

(75) Inventors: Masao Saitou, Tokyo (JP); Keiichi Takanashi, Tokyo (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: SUMCO CORPORATION, Tokyo (JP)

(21) Appl. No.: 12/819,930

(22) Filed: Jun. 21, 2010

(30) Foreign Application Priority Data
Jun. 22, 2009 (JP) 2009-147809
Jul. 29, 2009 (JP) 2009-176914

(51) Int. Cl. C30B 15/00

(52) U.S. Cl. 117/15; 117/14

(57) ABSTRACT

In a method of producing a silicon single crystal through a Czochralski method, the pulling process includes a process of conducting a neck trial pulling for the formation of a neck portion after a seed crystal is dipped into a melt and before a neck actual pulling for the formation of a neck portion is conducted, and it is judged whether or not a temperature of the melt is a temperature suitable for the formation of the neck portion from a change of a diameter in the neck portion formed by the neck trial pulling.

### BACKGROUND

1. Field of the Invention

This invention relates to a method of producing a silicon single crystal, and more especially to a method of producing a silicon single crystal using the Czochralski method.

2. Description of the Related Art

The silicon wafer used in the production of semiconductor devices is obtained mainly by slicing an ingot of silicon single crystal grown through the Czochralski method (CZ method). The CZ method is a method in which a seed crystal is dipped into a polycrystalline silicon melt in a quartz crucible and then pulled up while rotating the seed crystal and the quartz crucible in the opposite direction to each other to grow a silicon (Si) single crystal under the seed crystal.

Generally, when the seed crystal is dipped into the melt, the seed crystal is subjected to rapid thermal shock to cause dislocation in a tip portion of the seed crystal. In order to remove this dislocation, the shape of the growing interface needs to be convex relative to the melt. For making the growing interface convex, it is required to make the growth diameter small so as to increase release of heat from the surface. FIGS. 1(a) to 1(e) are schematic views for explaining such a process, illustrating that dislocation 103 generated when a seed crystal 101 is dipped into a melt 102 decreases as the seed crystal 101 is pulled. This process is generally referred to as necking.

An important point in this necking process is a temperature setting of the melt. As shown in FIGS. 2 and 3, the necking has been conducted using an apparatus provided with a temperature sensor 206, a heater control system 207 and a heater 208 wherein a surface temperature of a melt 202 was monitored with the temperature sensor 206 (e.g. a radiation thermometer or the like) and confirmed to be stable at a proper temperature (301) and thereafter a seed crystal 201 was dipped into the melt and then whether or not the temperature at a stage of a certain elapsed time is optimum is again judged (302) by the temperature sensor 206.

If the temperature of the melt was not suitable for forming a neck portion, the measured value by the temperature sensor 206 and a target temperature were fed back to the heater control system 207 for obtaining a proper temperature range (303), thereby stabilizing the temperature of the silicon melt.

However, there is a fear that the shape of the neck becomes unstable because an error is caused between a silicon melt temperature enabling neck formation and a value measured by the temperature sensor by change of production conditions and the like. As an example, when the temperature sensor is a radiation thermometer, there may be caused a case that a measured value and an actual temperature are different from each other due to fogging of a thermometer window and the like. Specifically, when the temperature of the silicon melt is too high, the neck is separated from the melt in the neck formation, while when the temperature of the silicon melt is low, there is a problem that the neck cannot be formed since the shape of the neck does not become thin.

Also, it is demanded to control the temperature of the melt more accurately in association with the recent widening in a diameter of a semiconductor silicon wafer, and hence it is required to use a temperature control means with a higher accuracy than that of the temperature sensor.

### SUMMARY

It is, therefore, an object of the invention to provide a method of producing a silicon single crystal wherein a melt temperature in the neck formation is properly controlled so as to render into a temperature suitable for the formation of a neck portion to thereby improve a success rate of forming the neck portion and attain a process efficiency.

In order to achieve the above object, the summary and construction of the invention are as follows:

(1) A method of producing a silicon single crystal through a Czochralski method comprising a melting process in which a polycrystalline silicon material is filled in a crucible and melted under heating to form a polycrystalline silicon melt, and a pulling process in which a seed crystal is dipped into the melt and a silicon single crystal having a given shape is formed while pulling the seed crystal upward under conditions of given temperature and pulling speed,
wherein the pulling process includes a process of conducting a neck trial pulling for the trial formation of a neck portion after the seed crystal is dipped into the melt set at a given temperature and before a neck actual pulling for the formation of a neck portion is conducted, and it is judged whether or not the temperature of the melt is a temperature suitable for the formation of the neck portion from a change of a diameter in the neck portion formed by the neck trial pulling.

(2) A method of producing a silicon single crystal according to the item (1), wherein as a result of the judgment that the temperature of the melt is a temperature unsuitable for the formation of the neck portion, the neck trial pulling is conducted again after the temperature of the melt is adjusted to stabilize the melt.

(3) A method of producing a silicon single crystal according to the item (1), wherein as a result of the judgment, a value of a temperature sensor measuring the temperature of the melt is corrected when the temperature of the melt has been adjusted at least once.

(4) A method of producing a silicon single crystal according to the item (1), wherein as a result of the judgment that the temperature of the melt is a temperature suitable for the formation of the neck portion, the neck trial pulling is followed by the neck actual pulling.

(5) A method of producing a silicon single crystal according to the item (3), wherein the temperature sensor is a radiation thermometer.

(6) A method of producing a silicon single crystal according to the item (2), wherein the adjustment on the temperature of the melt is conducted according to the following expressions:

T₁=T₀+H×(X−P) (1)

H=0.95

provided that a melt temperature after adjustment is T₁ [° C.], a melt temperature before adjustment is T₀ [° C.], a temperature correction factor is H [° C./mm], a target diameter of a neck portion formed by neck trial pulling is P [mm] and a diameter of a neck portion formed by neck trial pulling is X [mm].

(7) A method of producing a silicon single crystal according to the item (3), wherein the correction on the value of the temperature sensor is conducted according to the following expressions:

T₃=kT₂ (2)

k=k′×T₄/T₅

provided that a display temperature after correction is T₃ [° C.], a melt temperature conversion factor after correction is k, a display temperature before correction is T₂ [° C.], a melt temperature conversion factor before correction is k′, an initial target temperature is T₄ [° C.] and a final target temperature is T₅ [° C.].

(8) A method of producing a silicon single crystal through a Czochralski method comprising a melting process in which a polycrystalline silicon material is filled in a crucible and melted under heating to form a polycrystalline silicon melt, and a pulling process in which a seed crystal is dipped into the melt and a silicon single crystal having a given shape is formed while pulling the seed crystal upward under conditions of given temperature and pulling speed,
wherein the pulling process includes a process of conducting a neck trial pulling for the trial formation of a neck portion after the seed crystal is dipped into the melt set at a given temperature and before a neck actual pulling for the formation of a neck portion is conducted, and it is judged whether or not the temperature of the melt is a temperature suitable for the formation of the neck portion from a change of a diameter in the neck portion formed by the neck trial pulling and a speed of the neck trial pulling.

(9) A method of producing a silicon single crystal according to the item (8), wherein as a result of the judgment that the temperature of the melt is a temperature unsuitable for the formation of the neck portion, the neck trial pulling is conducted again after the temperature of the melt is adjusted to stabilize the melt.

(10) A method of producing a silicon single crystal according to the item (8), wherein as a result of the judgment, a value of a temperature sensor measuring the temperature of the melt is corrected when the temperature of the melt has been adjusted at least once.

(11) A method of producing a silicon single crystal according to the item (8), wherein as a result of the judgment that the temperature of the melt is a temperature suitable for the formation of the neck portion, the neck trial pulling is followed by the neck actual pulling.

(12) A method of producing a silicon single crystal according to the item (10), wherein the temperature sensor is a radiation thermometer.

(13) A method of producing a silicon single crystal according to the item (9), wherein the adjustment on the temperature of the melt is conducted according to the following expressions:

T₁=T₀+H×(X−P)×(Y/Q) (3)

H=0.95

provided that a melt temperature after adjustment is T₁ [° C.], a melt temperature before adjustment is T₀ [° C.], a temperature correction factor is H [° C.·mm²/s], a target diameter of a neck portion formed by neck trial pulling is P [mm], a diameter of a neck portion formed by neck trial pulling is X [mm], a target speed of pulling a neck portion is Q [mm/s]; and a speed of neck trial pulling is Y [mm/s].

(14) A method of producing a silicon single crystal according to the item (12), wherein the correction on the value of the temperature sensor is conducted according to the following expressions:

k=k′×M(λ,T₅)/M(λ,T₄) (4)

M(λ,Tₓ)=C₁/λ⁵×1/{exp(C₂/λTₓ)−1}

T₃=(C₂λ)(1/ln((C₁/λ⁵)(1/E)+1))
(wherein E=(k/k′)M(λ,T₂);
C₁: first constant of radiation (3.7415×10⁻¹⁶)[W·m²]; and
C₂: second constant of radiation (0.014388)[m·K])
   provided that a display temperature after correction is T₃ [K], a melt temperature conversion factor after correction is k, a display temperature before correction is T₂ [K], a melt temperature conversion factor before correction is k′, spectral radiant energy from an object is M (λ, Tₓ) [W·m⁻³], a measuring central wavelength of a radiation thermometer is λ [m], a melt temperature setting value in neck trial pulling is T₄ [K], and a value of a temperature sensor in neck trial pulling is T₅ [K].

(15) A method of producing a silicon single crystal according to the item (10), wherein the correction on the value of the temperature sensor is conducted according to the following expressions:

T₃=kT₂ (5)

k=k′×T₆/T₇

provided that a display temperature after correction is T₃ [° C.], a melt temperature conversion factor after correction is k, a display temperature before correction is T₂ [° C.], a melt temperature conversion factor before correction is k′, an initial target temperature is T₆ [° C.] and a final target temperature is T₇ [° C.].

According to the invention, there can be provided a method of producing a silicon single crystal wherein the single crystal pulling process of the Czochralski method includes a process of conducting a neck trial pulling for the trial formation of a neck portion after a seed crystal is dipped into a melt set at a given temperature and before a neck actual pulling for the formation of a neck portion is conducted, and it is judged whether or not the temperature of the melt is a temperature suitable for the formation of the neck portion from a change of a diameter in the neck portion formed by the neck trial pulling, whereby a success rate of forming the neck portion is improved to attain a process efficiency.

According to the invention, there can be also provided a method of producing a silicon single crystal wherein the single crystal pulling process of the Czochralski method includes a process of conducting a neck trial pulling for the trial formation of a neck portion after a seed crystal is dipped into a melt set at a given temperature and before a neck actual pulling for the formation of a neck portion is conducted, and it is judged whether or not the temperature of the melt is a temperature suitable for the formation of the neck portion from a change of a diameter in the neck portion formed by the neck trial pulling and a speed of the neck trail pulling, whereby a success rate of forming the neck portion is improved to attain a process efficiency.

### DESCRIPTION OF THE DRAWINGS

The invention will be described with reference to the accompanying drawings, wherein

FIGS. 1(a) to 1(e) are schematic views illustrating a necking process;

FIG. 2 is a schematic view illustrating a conventional apparatus for controlling a melt temperature;

FIG. 3 is a flow chart illustrating a conventional method for controlling a melt temperature;

FIG. 4 is a schematically cross-sectional view for illustrating a neck trial pulling according to the invention;

FIG. 5 is a schematic view illustrating an apparatus for controlling a melt temperature inclusive of a diameter measuring system; and

FIG. 6 is a flow chart illustrating a method of controlling a melt temperature control according to the invention.

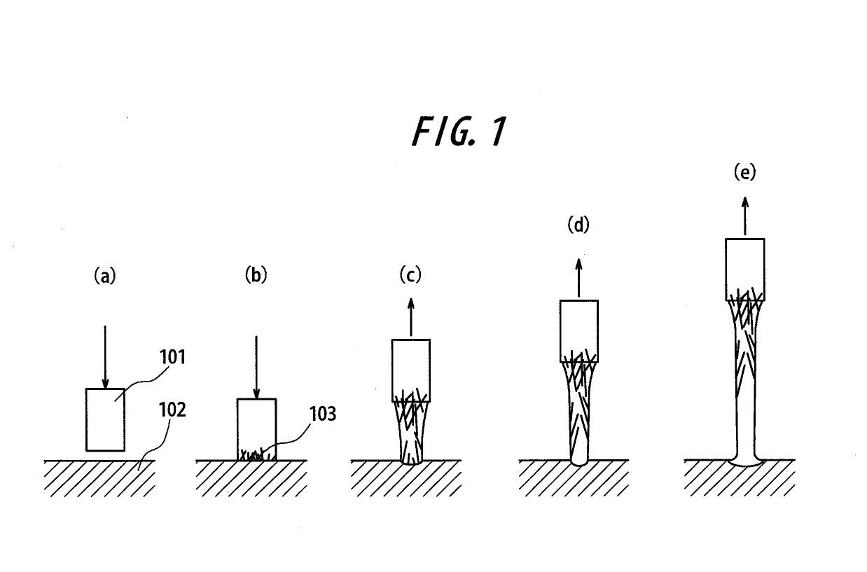

### DETAILED DESCRIPTION

Next, an embodiment of the method of producing a silicon single crystal as the first aspect of the invention will be described with reference to the drawings. As shown in FIG. 4, the production method of the silicon single crystal according to the invention is a method of producing a silicon single crystal through a Czochralski method comprising a melting process in which a polycrystalline silicon material is filled in a crucible 104 and melted under heating to form a polycrystalline silicon melt 102, and a pulling process in which a seed crystal 101 is dipped into the melt 102 and a silicon single crystal having a given shape is formed while pulling the seed crystal 101 upward under conditions of given temperature and pulling speed, wherein the pulling process includes a process of conducting a neck trial pulling for the trial formation of a neck portion after the seed crystal 101 is dipped into the melt 102 set at a given temperature and before a neck actual pulling for the formation of a neck portion is conducted, and it is judged (i.e., determined) whether or not the temperature of the melt 102 is a temperature suitable for the formation of the neck portion from a change of a diameter in a portion 105 located beneath the seed crystal as a neck portion formed by the neck trial pulling. According to such a construction, a success rate of forming the neck portion can be improved to attain a process efficiency.

The term “temperature suitable for the formation of a neck portion” used herein means a temperature at which a diameter of a portion located beneath the seed crystal is not changed when the seed crystal is brought into contact with the silicon melt and pulled at a given pulling speed.

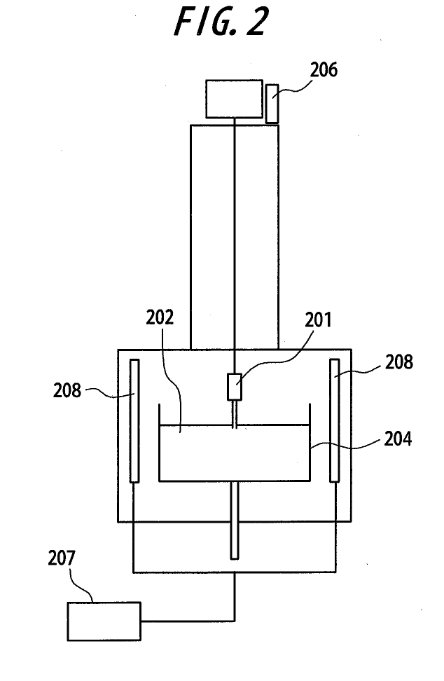

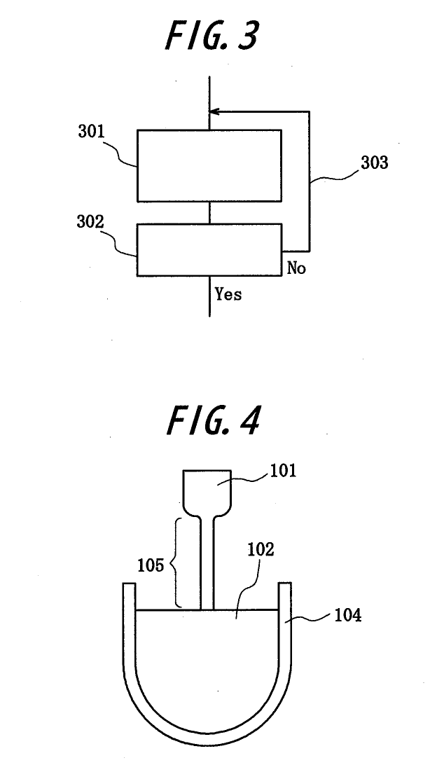

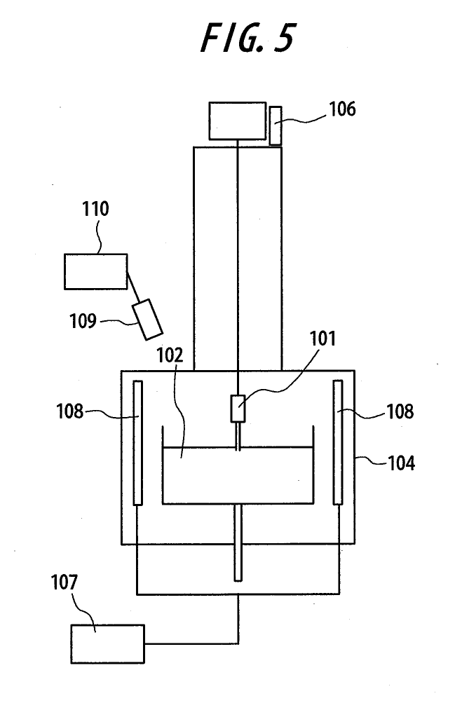

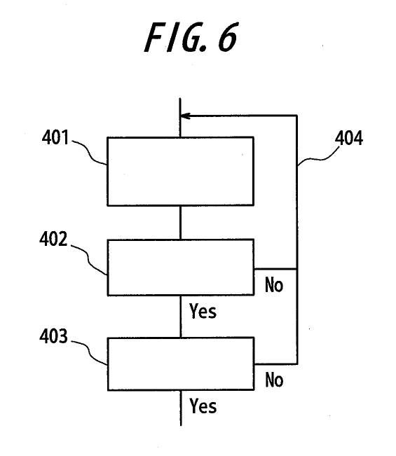

FIGS. 5 and 6 are respectively a schematic view and a flow chart of an apparatus constituted by adding a diameter measuring system 110 provided with a camera 109 to the conventional apparatus of FIG. 2. In this case, the diameter of the portion 105 formed by the neck trial pulling and located beneath the seed crystal is measured by the camera 109 (403), while the temperature of the melt 102 is monitored (401, 402) by a temperature sensor 106, and both of these measured results are fed back (404) to a heater control system 107.

As a result of judgment by comparing the thus measured inclination data, an average value, a maximum value and a minimum value on the diameter of the portion 105 formed by neck trial pulling and located beneath the seed crystal with an allowable diameter set by parameters for judging a temperature stability of the melt, when the temperature of the melt 102 is judged to be a temperature unsuitable for the formation of a neck portion, it is preferable to conduct the neck trial pulling again after the temperature of the melt 102 is adjusted to stabilize the melt. In this case, the unsuitable portion 105 formed by the neck trial pulling and located beneath the seed crystal can be reused by melting in the melt.

The adjustment on the temperature of the melt 102 is preferable to be conducted according to the following expressions:

T₁=T₀+H×(X−P) (1)

H=0.95

provided that a melt temperature after adjustment is T₁ [° C.], a melt temperature before adjustment is T₀ [° C.], a temperature correction factor is H [° C./mm], a target diameter of a neck portion formed by neck trial pulling is P [mm] and a diameter of a neck portion formed by neck trial pulling is X [mm] Moreover, the temperature correction factor H is a value obtained through experiments.

On the other hand, when the temperature of the melt 102 is judged to be a temperature suitable for the formation of the neck portion, the neck trial pulling is preferably followed by the neck actual pulling.

When the temperature of the melt 102 has been adjusted at least once as a result of the judgment, it is preferable to correct a value of a temperature sensor measuring the temperature of the melt. Such a correction is preferable to be conducted according to the following expression:

T₃=kT₂ (2)

k=k′×T₄/T₅

provided that a display temperature after correction is T₃ [° C.], a melt temperature conversion factor after correction is k, a display temperature before correction is T₂ [° C.], a melt temperature conversion factor before correction is k′, an initial target temperature is T₄ [° C.] and a final target temperature is T₅ [° C.].

The temperature sensor can be a thermocouple, a radiation thermometer or the like. In particular, it is preferable to use the radiation thermometer in terms of its easy installment to the apparatus, maintenance and the like.

Next, an embodiment of the method of producing a silicon single crystal as the second aspect of the invention will be described with reference to the drawings.

Such a production method of the silicon single crystal according to the invention is a method of producing a silicon single crystal using the Czochralski method likewise the first aspect of the invention. In particular, the pulling process includes a process of conducting a neck trial pulling for the trial formation of a neck portion after the seed crystal 101 is dipped into the melt 102 set at a given temperature and before a neck actual pulling for the formation of a neck portion is conducted, and it is judged whether or not the temperature of the melt 102 is a temperature suitable for the formation of the neck portion from a change of a diameter in a portion 105 located beneath the seed crystal as a neck portion formed by the neck trial pulling and a speed of the neck trial pulling According to such a construction, a success rate of forming the neck portion can be improved to attain a process efficiency.

The adjustment on the temperature of the melt 102 is preferable to be conducted according to the following expression:

T₁=T₀+H×(X−P)×(Y/Q) (3)

H=0.95

provided that a melt temperature after adjustment is T₁ [° C.], a melt temperature before adjustment is T₀ [° C.], a temperature correction factor is H [° C.·mm²/s], a target diameter of a neck portion formed by neck trial pulling is P [mm], a diameter of a neck portion formed by neck trial pulling is X [mm], a target speed of pulling a neck portion is Q [mm/s] and a speed of neck trial pulling is Y [mm/s] Moreover, the temperature correction factor H is a value obtained through experiments.

On the other hand, when the temperature of the melt 102 is judged to be a temperature suitable for the formation of the neck portion, the neck trial pulling is preferably followed by the neck actual pulling likewise the first aspect of the invention.

When the temperature of the melt 102 has been adjusted at least once as a result of the judgment, it is preferable to correct a value of a temperature sensor measuring the temperature of the melt. Such a correction is preferable to be conducted according to the following expression:

T₃=kT₂ (5)

k=k′×T₆/T₇

provided that a display temperature after correction is T₃ [° C.], a melt temperature conversion factor after correction is k, a display temperature before correction is T₂ [° C.], a melt temperature conversion factor before correction is k′, an initial target temperature is T₆ [° C.] and a final target temperature is T₇ [° C.]. At this moment, the initial target temperature means a temperature of the melt before the adjustment, and the final target temperature means a temperature of the melt after the adjustment.

As the temperature sensor is preferably used a radiation thermometer as previously mentioned because of non-contact measurement.

Moreover, the correction on the value of the radiation thermometer is preferable to be conducted according to the following expression:

k=k′×M(λ,T₅)/M(λ,T₄) (4)

M(λ,Tₓ)=C₁/λ⁵×1/{exp(C₂/λTₓ)−1}

T₃=(C₂/λ)(1/ln((C₁/λ⁵)(1/E)+1))
(wherein E=(k/k′)M(λ,T₂);
C₁: first constant of radiation (3.7415×10⁻¹⁶)[W·m²]; and
C₂: second constant of radiation (0.014388)[m·K])
   provided that a display temperature after correction is T₃ [K], a melt temperature conversion factor after correction is k, a display temperature before correction is T₂ [K], a melt temperature conversion factor before correction is k′, spectral radiant energy from an object is M(λ,Tₓ)[W·m⁻³], a measuring central wavelength of a radiation thermometer is λ [m], a melt temperature setting value in neck trial pulling is T₄ [K], a value of a temperature sensor in neck trial pulling is T₅ [K].

The above is described as an example, and the invention is not limited to such embodiments.

### Example 1

A silicon melt is formed with an apparatus shown in FIG. 5 by filling silicon material into a crucible and then melting under heating in an argon gas atmosphere under an internal pressure of 2666 Pa. The temperature of the silicon melt is measured by a radiation thermometer and adjusted to be about 1420° C. Thereafter, a seed crystal is dipped into the melt, and neck trial pulling is conducted by pulling the seed crystal in the same atmosphere at a seed crystal rotation speed of 12 rpm, a crucible rotation speed of 15 rpm and a pulling speed of 1 to 2 mm/min. In this case, it is judged whether or not the temperature of the melt is a temperature suitable for the formation of a neck portion from a change of a diameter in the neck portion formed by the neck trial pulling. As a result, when the temperature of the melt is judged to be a temperature unsuitable for the formation of the neck portion, the melt temperature is adjusted to a temperature suitable for the formation of the neck portion to stabilize the melt. The adjustment on the temperature of the melt is conducted according to the above expression 1, and the diameter X is determined based on an image taken with a camera.

When the temperature of the melt has been adjusted at least once as a result of the judgment, a value of the radiation thermometer measuring the temperature of the melt is corrected. The correction is conducted according to the above expression 2. Here, T₄=1450 and T₅=1452 are given.

### Comparative Example 1

A neck portion is formed in the same manner as in Example 1 except that the neck trial pulling is not conducted.

(Evaluation 1)

30 neck portions are formed by each production method of Example 1 and Comparative Example 1, among which neck portions formed with a diameter in an appropriate range are considered to be of success, and a success rate of neck formation is calculated and shown in Table 1.

TABLE 1

| | Success rate of neck formation (%) |
|---|---|
| Example 1 | 98 |
| Comparative Example 1 | 89 |

As seen from the results of Table 1, the success rate of neck formation is improved with respect to the neck portion produced by the method of the invention as compared with Comparative Example 1 conducting no neck trial pulling.

### Example 2

A neck trial pulling is conducted with an apparatus shown in FIG. 5 by pulling a seed crystal under the same conditions as in Example 1. In this case, it is judged whether or not the temperature of the melt is a temperature suitable for the formation of a neck portion from a change of a diameter in the neck portion formed by the neck trial pulling and a speed of the neck trial pulling. As a result, when the temperature of the melt is judged to be a temperature unsuitable for the formation of a neck portion, the melt temperature is adjusted to a temperature suitable for the formation of a neck portion to stabilize the melt. The adjustment on the temperature of the melt is conducted according to the above expression 3, and the diameter X and the speed of neck trial pulling Y are determined based on an image taken with a camera.

When the temperature of the melt has been adjusted at least once as a result of the judgment, a value of the radiation thermometer measuring the temperature of the melt is corrected. Such a correction is conducted according to the above expression 4 provided that a display temperature before correction T₂ is 1455° C., a melt temperature conversion factor before correction k′ is 0.2, spectral radiant energy from an object is M (λ,Tₓ) [W·m⁻³], a measuring central wavelength of a radiation thermometer λ is 0.9 μm, a melt temperature setting value in neck trial pulling T₄ is 1450° C., and a value of a temperature sensor in neck trial pulling T₅ is 1452° C.

According to this expression, a display temperature after correction T₃ is 1457° C. and a melt temperature conversion factor after correction k is 0.202.

### Comparative Example 2

A neck portion is formed in the same manner as in Example 2 except that the neck trial pulling is not conducted.

(Evaluation 2)

30 neck portions are formed by each production method of Example 2 and Comparative Example 2, and a success rate of neck formation is calculated and shown in Table 2. Here, the neck formation success means that the neck shape is within a controlled value, while the neck formation failure means that the neck shape is out of a controlled value.

TABLE 2

| | Success rate of neck formation (%) |
|---|---|
| Example 2 | 98 |
| Comparative Example 2 | 89 |

As seen from the results of Table 2, the success rate of neck formation is improved with respect to the neck portion produced by the method of the invention as compared with Comparative Example 2 conducting no neck trial pulling.

According to the invention, there can be provided a method of producing a silicon single crystal wherein the pulling process includes a process of conducting a neck trial pulling for the trial formation of a neck portion after a seed crystal is dipped into a melt set at a given temperature and before a neck actual pulling for the formation of a neck portion is conducted, and it is judged whether or not the temperature of the melt is a temperature suitable for the formation of the neck portion from a change of a diameter in the neck portion formed by the neck trial pulling, whereby a success rate of forming the neck portion is improved to attain a process efficiency.

According to the invention, there can be also provided a method of producing a silicon single crystal wherein the pulling process includes a process of conducting a neck trial pulling for the trial formation of a neck portion after a seed crystal is dipped into a melt set at a given temperature and before a neck actual pulling for the formation of a neck portion is conducted, and it is judged whether or not the temperature of the melt is a temperature suitable for the formation of the neck portion from a change of a diameter in the neck portion formed by the neck trial pulling and a speed of the neck trail pulling, whereby a success rate of forming the neck portion is improved to attain a process efficiency.

What is claimed is:

1. A method of producing a silicon single crystal through a Czochralski method comprising a melting process in which a polycrystalline silicon material is filled in a crucible and melted under heating to form a polycrystalline silicon melt, and a pulling process in which a seed crystal is dipped into the melt and a silicon single crystal having a given shape is formed while pulling the seed crystal upward under conditions of given temperature and pulling speed,
wherein the pulling process includes a process of conducting a neck trial pulling for the trial formation of a neck portion after the seed crystal is dipped into the melt set at a given temperature and before a neck actual pulling for the formation of a neck portion is conducted, and it is judged whether or not the temperature of the melt is a temperature suitable for the formation of the neck portion from a change of a diameter in the neck portion formed by the neck trial pulling.

2. A method of producing a silicon single crystal according to claim 1, wherein as a result of the judgment that the temperature of the melt is a temperature unsuitable for the formation of the neck portion, the neck trial pulling is conducted again after the temperature of the melt is adjusted to stabilize the melt.

3. A method of producing a silicon single crystal according to claim 2, wherein the adjustment on the temperature of the melt is conducted according to the following expressions:
T₁=T₀+H×(X−P)
H=0.95
provided that a melt temperature after adjustment is T₁ [° C.], a melt temperature before adjustment is T₀ [° C.], a temperature correction factor is H [° C./mm], a target diameter of a neck portion formed by neck trial pulling is P [mm] and a diameter of a neck portion formed by neck trial pulling is X [mm].

4. A method of producing a silicon single crystal according to claim 1, wherein as a result of the judgment, a value of a temperature sensor measuring the temperature of the melt is corrected when the temperature of the melt has been adjusted at least once.

5. A method of producing a silicon single crystal according to claim 4, wherein the temperature sensor is a radiation thermometer.

6. A method of producing a silicon single crystal according to claim 4, wherein the correction on the value of the temperature sensor is conducted according to the following expressions:
T₃=kT₂
k=k′×T₄/T₅
provided that a display temperature after correction is T₃ [° C.], a melt temperature conversion factor after correction is k, a display temperature before correction is T₂ [° C.], a melt temperature conversion factor before correction is k′, an initial target temperature is T₄ [° C.] and a final target temperature is T₅ [° C.].

7. A method of producing a silicon single crystal according to claim 1, wherein as a result of the judgment that the temperature of the melt is a temperature suitable for the formation of the neck portion, the neck trial pulling is followed by the neck actual pulling.

8. A method of producing a silicon single crystal through a Czochralski method comprising a melting process in which a polycrystalline silicon material is filled in a crucible and melted under heating to form a polycrystalline silicon melt, and a pulling process in which a seed crystal is dipped into the melt and a silicon single crystal having a given shape is formed while pulling the seed crystal upward under conditions of given temperature and pulling speed,
wherein the pulling process includes a process of conducting a neck trial pulling for the trial formation of a neck portion after the seed crystal is dipped into the melt set at a given temperature and before a neck actual pulling for the formation of a neck portion is conducted, and it is judged whether or not the temperature of the melt is a temperature suitable for the formation of the neck portion from a change of a diameter in the neck portion formed by the neck trial pulling and a speed of the neck trial pulling.

9. A method of producing a silicon single crystal according to claim 8, wherein as a result of the judgment that the temperature of the melt is a temperature unsuitable for the formation of the neck portion, the neck trial pulling is conducted again after the temperature of the melt is adjusted to stabilize the melt.

10. A method of producing a silicon single crystal according to claim 9, wherein the adjustment on the temperature of the melt is conducted according to the following expressions:
T₁=T₀+H×(X−P)×(Y/Q)
H=0.95
provided that a melt temperature after adjustment is T₁ [° C.], a melt temperature before adjustment is T₀ [° C.], a temperature correction factor is H [° C.·mm²/s], a target diameter of a neck portion formed by neck trial pulling is P [mm], a diameter of a neck portion formed by neck trial pulling is X [mm], a target speed of pulling a neck portion is Q [mm/s] and a speed of neck trial pulling is Y [mm/s].

11. A method of producing a silicon single crystal according to claim 8, wherein as a result of the judgment, a value of a temperature sensor measuring the temperature of the melt is corrected when the temperature of the melt has been adjusted at least once.

12. A method of producing a silicon single crystal according to claim 11, wherein the temperature sensor is a radiation thermometer.

13. A method of producing a silicon single crystal according to claim 12, wherein the correction on the value of the temperature sensor is conducted according to the following expressions:
k=k′×M(λ,T₅)/M(λ,T₄
M(λ,Tₓ)=C₁/λ⁵×1/{exp(C₂λTₓ)−1}
T₃=(C₂/λ)(1/ln((C₁/λ⁵)(1/E)+1))
(wherein E=(k/k′)M(λ,T₂);
C₁: first constant of radiation (3.7415×10⁻¹⁶)[W·m²]; and
C₂: second constant of radiation (0.014388)[m·K])
provided that a display temperature after correction is T₃ [K], a melt temperature conversion factor after correction is k, a display temperature before correction is T₂ [K], a melt temperature conversion factor before correction is k′, spectral radiant energy from an object is M (λ,Tₓ)[W·m⁻³], a measuring central wavelength of a radiation thermometer is λ[m], a melt temperature setting value in neck trial pulling is T₄ [K] and a value of a temperature sensor in neck trial pulling is T₅ [K].

14. A method of producing a silicon single crystal according to claim 11, wherein the correction on the value of the temperature sensor is conducted according to the following expressions:
T₃=kT₂
k=k′×T₆/T₇
provided that a display temperature after correction is T₃ [° C.], a melt temperature conversion factor after correction is k, a display temperature before correction is T₂ [° C.], a melt temperature conversion factor before correction is k′, an initial target temperature is T₆ [° C.] and a final target temperature is T₇ [° C.].

15. A method of producing a silicon single crystal according to claim 8, wherein as a result of the judgment that the temperature of the melt is a temperature suitable for the formation of the neck portion, the neck trial pulling is followed by the neck actual pulling.
